(19) United States
(12) Patent Application Publication
(10) Pub. No.: US 2025/0259786 A1
(43) Pub. Date: Aug. 14, 2025

(54) QUBIT CAPACITOR AND QUANTUM CHIP

(71) Applicant: YANGTZE DELTA INDUSTRIAL INNOVATION CENTER OF QUANTUM SCIENCE AND TECHNOLOGY, Suzhou (CN)

(72) Inventors: Tian LUAN, Suzhou (CN); Zeyang ZHENG, Suzhou (CN); Haifeng LI, Suzhou (CN); Yun WANG, Suzhou (CN); Chengxin LI, Suzhou (CN); Huide ZHOU, Suzhou (CN)

(21) Appl. No.: 19/174,927

(22) Filed: Apr. 10, 2025

Related U.S. Application Data
(63) Continuation of application No. PCT/CN2024/115420, filed on Aug. 29, 2024.

(30) Foreign Application Priority Data
Oct. 18, 2023 (CN) 202311347863.1

(51) Int. Cl. H01G 2/00; H10N 60/12; H10N 60/80

(52) U.S. Cl. CPC H01G 2/00; H10N 60/12; H10N 60/805

(57) ABSTRACT

The application relates to the field of quantum computing, and discloses a qubit capacitor and a quantum chip, the qubit capacitor including: a first metal plate, a second metal plate, and a Josephson junction; wherein a first end of the Josephson junction is connected with the first metal plate, and a second end of the Josephson junction is connected with the second metal plate; a sub-metal sheet is arranged on the first metal plate and/or the second metal plate; and the length of the sub-metal sheet is smaller than that of the first metal plate and the second metal plate.

### CROSS-REFERENCE TO RELATED APPLICATIONS

The present application is a continuation of International Application No. PCT/CN2024/115420, with an international filing date of Aug. 29, 2024, which is based upon and claims priority to Chinese Patent Application No. 202311347863.1, filed on Oct. 18, 2023, the entire contents of all of which are incorporated herein by reference.

### TECHNICAL FIELD

The present disclosure relates to a technical field of quantum computing, particularly to a qubit capacitor and a quantum chip.

### BACKGROUND

Quantum chip is a core component of a quantum computer and integrates quantum bits and related lines on a substrate to carry the function of quantum information processing. Usually, a quantum chip includes a plurality of quantum devices such as qubit capacitors and resonant cavities. In a qubit capacitor, a coplanar waveguide (CPW) structure is generally formed by a single independent metal sheet and a chip ground. At present, the metal sheet of the qubit capacitor usually uses a cross-shaped metal sheet or an m-shaped metal sheet to increase the overlap area of the qubit capacitor, thereby increasing the capacitance value of the qubit capacitor.

FIG. 1 is a structural diagram of a cross-shaped qubit capacitor provided by an embodiment of the present disclosure. As shown in FIG. 1, the size of the qubit capacitor in the form of a cross-shaped metal sheet is comparable to that of a quarter-wavelength resonator in a meandering layout. In a quantum chip array, the qubit capacitor expands along two dimensional directions. With the increase of the number of the bits, the layout space reserved for pulse regulation and control signal lines (XY control lines), frequency regulation and control signal lines (Z control lines) and read lines of quantum bits is smaller, and therefore it usually needs to sacrifice the isolation index among the signal lines to meet the wiring requirements, which may cause mutual interference among different signal lines and affect the normal operation of the system. Meanwhile, when the capacitance value requirement of each qubit capacitor in the quantum chip array changes, the size of the qubit capacitor changes accordingly, resulting in the need for redesign of the quantum chip and increased design cost of the chip.

To sum up, how to provide a novel qubit capacitor to prevent the mutual interference among different signal lines caused by small wiring space is an urgent problem to be solved by those skilled in the art.

### SUMMARY

The present disclosure aims at solving the problem of mutual interference among different signal lines due to small layout space reserved for a qubit capacitor in the form of a cross-shaped metal sheet in the prior art, and the problem of increased design cost of the chip resulting from the need to redesign all the qubit capacitors in an array when the capacitance value requirement of the qubit capacitor changes during the design process. The present disclosure further provides a qubit capacitor and a quantum chip, thereby providing a larger line layout space to prevent different signal lines from interfering with each other.

In order to achieve the above purpose, the present disclosure provides a qubit capacitor, comprising:
a first metal plate, a second metal plate, and a Josephson junction;
wherein a first end of the Josephson junction is connected with the first metal plate, and a second end of the Josephson junction is connected with the second metal plate;
a sub-metal sheet is arranged on the first metal plate and/or the second metal plate; and
the length of the sub-metal sheet is smaller than that of the first metal plate and the second metal plate.

Optionally, the first metal plate and the second metal plate comprise a first metal arm and a second metal arm; and an angle between the first metal arm and the second metal arm is 90 degrees.

Optionally, the first metal plate and the second metal plate have the same shape and the same area.

Optionally, the sub-metal sheet comprises a first I-shaped metal sheet and a second I-shaped metal sheet;
wherein the first I-shaped metal sheet and the second I-shaped metal sheet comprise a third metal arm, a fourth metal arm and a fifth metal arm, respectively, and the third metal arm, the fourth metal arm and the fifth metal arm are linear metal arms;
the third metal arm is parallel to the fifth metal arm, and the third metal arm and the fifth metal arm are vertical to the fourth metal arm;
a first end of the fourth metal arm is connected with a midpoint of the third metal arm, and a second end of the fourth metal arm is connected with a midpoint of the fifth metal arm;
a center point of the fourth metal arm of the first I-shaped metal sheet is arranged on the first metal arm of the first metal plate and/or the second metal plate; and
a center point of the fourth metal arm of the second I-shaped metal sheet is arranged on the second metal arm of the first metal plate and/or the second metal plate.

Optionally, the sub-metal sheet is a snowflake metal sheet;
the snowflake metal sheet comprises a linear metal arm and at least one angular metal arm;
a right-angle vertex of each of the angular metal arms is arranged on the linear metal arm, one end of the linear metal arm is connected with an intersection point of the first metal arm and the second metal arm of the first metal plate and/or the second metal plate; and
an opening direction of each of the angular metal arms is the same as that of the metal plate to which the linear metal arm is connected.

Optionally, the sub-metal sheet comprises a first dumbbell-shaped metal sheet and a second dumbbell-shaped metal sheet;
wherein the first dumbbell-shaped metal sheet and the second dumbbell-shaped metal sheet comprise a first U-shaped metal arm, a second U-shaped metal arm and a linear metal arm;
a first end of the linear metal arm is connected with a midpoint of a bottom edge of the first U-shaped metal arm, and a second end of the linear metal arm is connected with a midpoint of a bottom edge of the second U-shaped metal arm; and
a midpoint of the linear metal arm of the first dumbbell-shaped metal sheet is fixed to the first metal arm and/or the second metal arm of the first metal plate, and a midpoint of the linear metal arm of the second dumbbell-shaped metal sheet is fixed to the first metal arm and/or the second metal arm of the second metal plate.

Optionally, the qubit capacitor further comprises: a pulse regulation and control signal line and a frequency regulation and control signal line;
wherein the pulse regulation and control signal line is connected with a control electrode of the qubit capacitor to control excited state of the qubit capacitor; and
the frequency regulation and control signal line is connected with the Josephson junction to control frequency of the qubit capacitor.

Optionally, the substrate of the first metal plate, the second metal plate and the sub-metal sheet is silicon or sapphire connected with the metal plate by bonding technique.

In order to achieve the above purpose, the present disclosure further provides a quantum chip comprising the qubit capacitor.

Optionally, each of the qubit capacitors is connected in a fixed coupling manner.

The present disclosure provides a qubit capacitor, comprising: a first metal plate, a second metal plate, and a Josephson junction; wherein a first end of the Josephson junction is connected with the first metal plate, and a second end of the Josephson junction is connected with the second metal plate; a sub-metal sheet is arranged on the first metal plate and/or the second metal plate; and the length of the sub-metal sheet is smaller than that of the first metal plate and the second metal plate. As can be seen, in the technical solution provided by the present disclosure, the first metal plate and the second metal plate are connected through the Josephson junction to form a double-island qubit capacitor, thereby providing a larger line layout space to prevent different signal lines from interfering with each other. Also, a sub-metal sheet is arranged on the first metal plate and the second metal plate, so as to achieve the purpose of increasing the shunt capacitance of the first metal plate and the second metal plate, and improving the equivalent capacitance value of the two parts of the double-island qubit capacitor. In addition, in the design stage of a qubit capacitor, the overall capacitance value of the qubit capacitor can be changed by adjusting the capacitance value of the sub-metal sheet without the need of adjusting the size of the qubit capacitor, thereby reducing the design cost.

The present disclosure provides a quantum chip comprising the above qubit capacitor with the same effect as above.

### BRIEF DESCRIPTION OF THE DRAWINGS

In order to more clearly explain the embodiments of the present disclosure, drawings required in the embodiments will be briefly described below. Obviously, the drawings in the following description are some embodiments of the present disclosure. For those skilled in the art, other drawings may be obtained from these drawings without any creative effort.

FIG. 1 is a structural diagram of a cross-shaped qubit capacitor provided by an embodiment of the present disclosure;

FIG. 2 is an equivalent circuit diagram of a cross-shaped qubit capacitor provided by an embodiment of the present disclosure;

FIG. 3 is a structural diagram of a double-island qubit capacitor provided by an embodiment of the present disclosure;

FIG. 4 is an equivalent circuit diagram of a double-island qubit capacitor provided by an embodiment of the present disclosure;

FIG. 5 is a structural diagram of a qubit capacitor provided by an embodiment of the present disclosure;

FIG. 6 is an equivalent circuit diagram of a qubit capacitor provided by an embodiment of the present disclosure;

FIG. 7 is a structural diagram of another I-shaped qubit capacitor provided by an embodiment of the present disclosure;

FIG. 8 is a schematic diagram of a qubit capacitor structure of a quantum chip provided by an embodiment of the present disclosure;

FIG. 9 is a structural diagram of a snowflake qubit capacitor provided by an embodiment of the present disclosure;

FIG. 10 is a structural diagram of another snowflake qubit capacitor provided by an embodiment of the present disclosure;

FIG. 11 is a schematic diagram of a qubit capacitor structure of another quantum chip provided by an embodiment of the present disclosure;

FIG. 12 is a structural diagram of a dumbbell-shaped qubit capacitor provided by an embodiment of the present disclosure.

### LIST OF REFERENCE NUMBERS

The reference numerals are shown as follows: 1 is a first metal plate, 2 is a second metal plate, 3 is a Josephson junction, 4 is a first metal arm, 5 is a second metal arm, 6 is a first I-shaped metal sheet, 7 is a second I-shaped metal sheet, 8 is a third metal arm, 9 is a fourth metal arm, 10 is a fifth metal arm, 11 is a linear metal arm of a snowflake qubit capacitor, 12 is an angular metal arm, 13 is a first dumbbell-shaped metal sheet, 14 is a second dumbbell-shaped metal sheet, 15 is a first U-shaped metal arm, 16 is a second U-shaped metal arm, 101 is a qubit capacitor, 102 is a cross-shaped qubit capacitor, 103 is a chip ground, 104 is a resonator, 105 is a Z control line, 106 is an XY control line, and 107 is a read line.

### DETAILED DESCRIPTION OF THE EMBODIMENTS

The technical solutions of the embodiments of the present disclosure will be described clearly and completely as follows with reference to the drawings in the embodiments of the present disclosure. Obviously, the described embodiments are part of, but not all of, the embodiments of the present disclosure. Based on the embodiments of the present disclosure, all the other embodiments obtained by those skilled in the art without paying any creative work fall within the protection scope of the present disclosure.

The core of the present disclosure is to provide a qubit capacitor and a quantum chip, thereby providing a larger line layout space to prevent the mutual interference among different signal lines and improving the reliability of the qubit capacitor.

In order to enable those skilled in the art to better understand the aspects of the present disclosure, the present disclosure will now be described in further detail with reference to the accompanying drawings and detailed description.

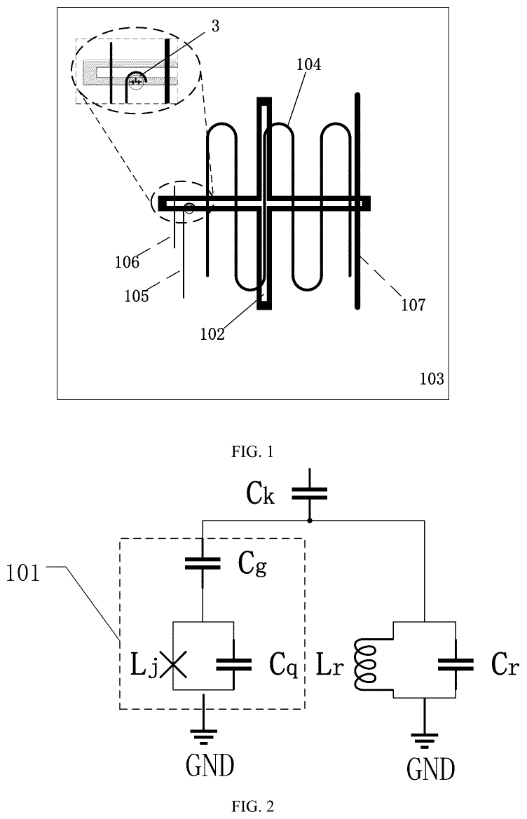

Quantum chip is a core component of a quantum computer and includes a plurality of quantum devices such as qubit capacitors and resonant cavities, etc. The qubit capacitor usually includes a metal sheet and a chip ground 103, and most of the metal sheets commonly used at present are cross-shaped metal sheets, so as to improve the coherence time of the qubit capacitor, and to realize better control accuracy and lower energy consumption. In addition, the design of the cross-shaped metal sheet can also improve the control accuracy of the quantum bit and reduce the energy consumption of the qubit capacitor, thereby improving the performance and reliability of the qubit capacitor and realizing more stable and more accurate quantum computing operation. The size of the qubit capacitor in the form of a cross-shaped metal sheet is comparable to that of a quarter-wavelength resonator in a meandering layout, for example, on a sapphire substrate having a thickness of 500 μm, when the capacitance value of the qubit capacitor is taken as 84 fF, the size of the cross-shaped qubit capacitor is about 550 um*550 μm, and the size of the quarter-wavelength resonator 104 in a meandering layout is about 420 um*420 um. With the increase of the number of the bits, the qubit capacitor expands along two dimensional directions, at this time, the layout space reserved for XY control line 106, Z control line 105 and read line 107 is smaller, which usually needs to sacrifice the isolation index among the signal lines to meet the wiring requirements, thereby affecting the normal operation of the quantum chip. FIG. 2 is an equivalent circuit diagram of a cross-shaped qubit capacitor provided by an embodiment of the present disclosure. As shown in FIG. 1 and FIG. 2, in the cross-shaped qubit capacitor 102, the Josephson junction 3 is connected between the metal plate 102 of the cross-shaped qubit capacitor and the chip ground 103 in a spanned mode, and the equivalent inductance is Lⱼ; a qubit capacitor C_{q} is formed between the metal plate of the cross-shaped qubit capacitor 102 and the chip ground 103; and the resonator 104, the Z control line 105, the XY control line 106, and the read line 107 are in non-coplanar coupling with the cross-shaped qubit capacitor 102. A coupling capacitance C_{g} is formed between the cross-shaped qubit capacitor 102 and the resonator 104. The Z control line 105 applies magnetic flux to the Josephson junction 3 through mutual inductance. With the increase of the number of the bits, the qubit capacitor expands along two dimensional directions, at this time, the layout space reserved for XY control line 106, Z control line 105 and read line 107 is smaller, which usually needs to sacrifice the isolation index among the signal lines to meet the wiring requirements. According to the equivalent circuit model and the series-parallel relationship in FIG. 1, the impedance in the dashed box can be obtained as follows:

$$Z = ( j ω {L}_{j} // \frac{1}{j ω {C}_{q}} ) + \frac{1}{j ω {C}_{g}} = \frac{1 - {ω}^{2} {L}_{j} ( {C}_{g} + {C}_{q} )}{j ω {C}_{g} ( 1 - {ω}^{2} {L}_{j} {C}_{q} )} ;$$

The numerator of the above formula is set as 0, considering C_{g}<<C_{q}, the series resonance frequency ω₀₁ can be obtained as:

$${ω}_{01} = \frac{1}{\sqrt{{L}_{j} ( {C}_{g} + {C}_{q} )}} \approx \frac{1}{\sqrt{{L}_{j} {C}_{q}}} ;$$

The denominator of the above formula is set as 0, the parallel resonance frequency ω₀₂ can be obtained as:

$${ω}_{02} = \frac{1}{\sqrt{{L}_{j} {C}_{q}}} ;$$

As can be seen, the actual capacitance value of the “cross-shaped” qubit capacitor is C_{q}.

In order to solve this problem, the present disclosure provides a qubit capacitor, including: a first metal plate 1, a second metal plate 2, and a Josephson junction 3; wherein a first end of the Josephson junction 3 is connected with the first metal plate 1, and a second end of the Josephson junction 3 is connected with the second metal plate 2; a sub-metal sheet is arranged on the first metal plate 1 and/or the second metal plate 2; and the length of the sub-metal sheet is smaller than that of the first metal plate 1 and the second metal plate 2. As can be seen, in the technical solution provided by the present disclosure, the first metal plate 1 and the second metal plate 2 are connected through the Josephson junction 3 to form a double-island qubit capacitor, thereby providing a larger line layout space to prevent different signal lines from interfering with each other. Meanwhile, a sub-metal sheet is arranged on the first metal plate 1 and the second metal plate 2, so as to achieve the purpose of increasing the shunt capacitance of the first metal plate 1 and the second metal plate 2, and improving the equivalent capacitance value of the two parts of the double-island qubit capacitor. In addition, in the design stage of a qubit capacitor, the overall capacitance value of the qubit capacitor can be changed by adjusting the capacitance value of the sub-metal sheet without the need of adjusting the size of the qubit capacitor, thereby reducing the design cost.

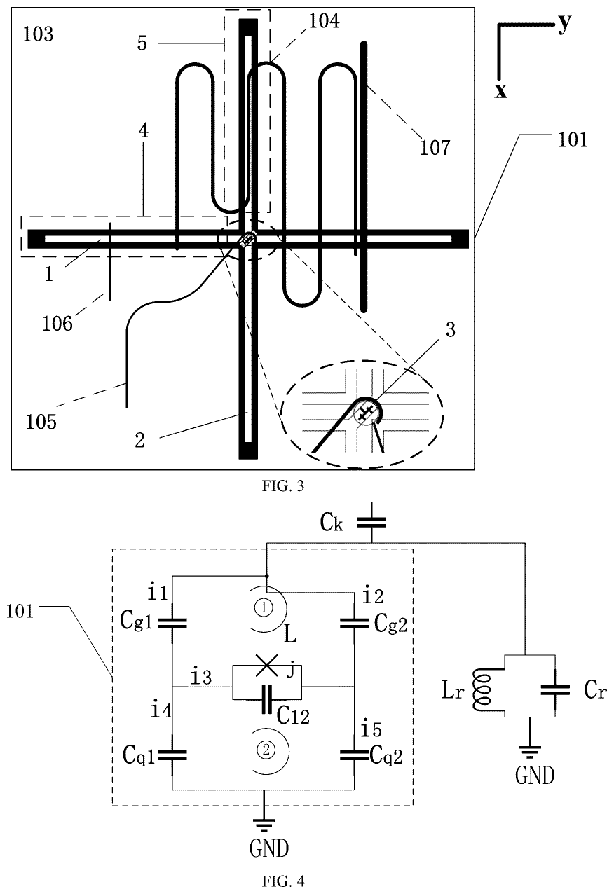

FIG. 3 is a structural diagram of a double-island qubit capacitor provided by an embodiment of the present disclosure. As shown in FIG. 3, the double-island structure includes two separated island-shaped metal sheets which are connected through a Josephson junction 3, and the Josephson junction 3 is connected between the first metal plate 1 and the second metal plate 2 of similar size in a spanned mode, with an equivalent inductance being Lⱼ. The first metal plate 1 and the second metal plate 2 are bent into a shape of 90°, a self-capacitor C_{q1} and a self-capacitor C_{q2} are formed between the first metal plate 1 and the chip ground 103, and between the second metal plate 2 and the chip ground 103, respectively, and a coupling capacitor C₁₂ is formed between the first metal plate 1 and the second metal plate 2. The resonator 104, the Z control line 105, the XY control line 106, and the read line 107 are in non-coplanar coupling with the first metal plate 1 and the second metal plate 2 of the double-island qubit capacitor, wherein a coupling capacitance C_{g1} and a coupling capacitance C_{g2} are formed between the resonator 104 and the first metal plate 1 and between the resonator 104 and the second metal plate 2, respectively. FIG. 4 is an equivalent circuit diagram of a double-island qubit capacitor provided by an embodiment of the present disclosure. According to Kirchhoff laws, an equation set can be made as follows:

$$\{ \begin{matrix}I = {i}_{1} + {i}_{2} = {i}_{4} + {i}_{5} \\ {i}_{1} = {i}_{3} + {i}_{4} \\ {i}_{5} = {i}_{2} + {i}_{3}\end{matrix} ;$$

wherein, i₁, i₂, i₃, i₄, i₅ are the current values of each circuit in FIG. 4, respectively, and I is the current value in the main circuit.

In circuit \textcircled{1}, it can be obtained:

$${i}_{2} \frac{1}{j ω {C}_{g 2}} - {i}_{3} {Z}_{j} - {i}_{1} \frac{1}{j ω {C}_{g 1}} = 0 ;$$

In circuit \textcircled{2}, it can be obtained:

$${i}_{3} {Z}_{j} + {i}_{5} \frac{1}{j ω {C}_{q 2}} - {i}_{4} \frac{1}{j ω {C}_{q 1}} = 0 ;$$

wherein, jω is a plural unit,

$${Z}_{j} = j ω {L}_{j} // \frac{1}{j ω {C}_{12}} = \frac{j ω {L}_{j} \cdot \frac{1}{j ω {C}_{12}}}{j ω {L}_{j} + \frac{1}{j ω {C}_{12}}} = \frac{j ω {L}_{j}}{1 - {ω}^{2} {L}_{j} {C}_{12}} ;$$

After expressing i₂, i₃, i₄, and is in terms of i₁, the impedance in the dashed box is obtained as:

$$Z = \frac{U}{I} = \frac{\begin{matrix}{ω}^{2} {L}_{j} ( {C}_{q 1} + {C}_{g 1} ) ( {C}_{q 2} + {C}_{g 2} ) + \\ ( {ω}^{2} {L}_{j} {C}_{12} - 1 ) ( {C}_{q 1} + {C}_{q 2} + {C}_{g 1} + {C}_{g 2} )\end{matrix}}{\begin{matrix}j ω \{ [ {ω}^{2} {L}_{j} {C}_{q 1} {C}_{q 2} + ( {ω}^{2} {L}_{j} {C}_{12} - 1 ) ( {C}_{q 1} + {C}_{q 2} ) ] \\ ( {C}_{g 1} + {C}_{g 2} ) + {ω}^{2} {L}_{j} {C}_{g 2} {C}_{g 1} ( {C}_{q 1} + {C}_{q 2} ) \}\end{matrix}}$$

From numerator=0, considering that C_{g1}, C_{g2} and C₁₂ are much smaller than C_{q1} and C_{q2}, the series resonance frequency can be obtained as:

$$ω = \sqrt{\frac{{C}_{q 1} + {C}_{q 2} + {C}_{g 1} + {C}_{g 2}}{{L}_{j} ( {C}_{q 1} + {C}_{g 1} ) ( {C}_{q 2} + {C}_{g 2} ) + {L}_{j} {C}_{12} ( {C}_{q 1} + {C}_{q 2} + {C}_{g 1} + {C}_{g 2} )}} \approx \sqrt{\frac{1}{{L}_{j} {C}_{q}}} ;$$

wherein

$${C}_{q} = \frac{{C}_{q 1} {C}_{q 2}}{{C}_{q 1} + {C}_{q 2}}$$

is an approximate equivalent qubit capacitor.

Similarly, from denominator=0, considering that C_{g1}, C_{g2} and C₁₂ are much smaller than C_{q1} and C_{q2}, the parallel resonance frequency can be obtained as:

$$ω = \sqrt{\frac{( {C}_{1} + {C}_{2} ) ( {C}_{g 1} + {C}_{g 2} )}{{L}_{j} [ \begin{matrix}{C}_{1} {C}_{2} ( {C}_{g 1} + {C}_{g 2} ) + {C}_{g 2} {C}_{g 1} ( {C}_{1} + {C}_{2} ) + \\ {C}_{12} ( {C}_{1} + {C}_{2} ) ( {C}_{g 1} + {C}_{g 2} )\end{matrix} ]}} \approx \sqrt{\frac{1}{{L}_{j} {C}_{q}}} ;$$

wherein

$${C}_{q} = \frac{{C}_{q 1} {C}_{q 2}}{{C}_{q 1} + {C}_{q 2}} .$$

Since the double-island qubit capacitor is composed of two metal sheets with similar sizes, under the same size, C_{g1}≈C_{q2}≈2C_{q} can be obtained, and compared with the traditional “m-shaped” structure, the overall size of the double-island structure is larger, leaving more space for the signal line and the read line 107, which is more beneficial to the layout in the chip. However, in the double-island structure, the Josephson junction 3 needs to be connected between the first metal plate and the second metal plate in a spanned manner, i.e., the Z control line 105 needs to extend to the central area of the qubit capacitor to apply the magnetic flux to the Josephson junction 3, so that the wiring of the resonator 104 needs to bypass the central area of the qubit capacitor (the dashed box region) and the wiring area of the Z control line 105 (the lower left corner), as shown in FIG. 3.

For a given design capacitance value C_{q} (a sum of capacitance values of C_{q1} and C_{q2} in parallel), when the design capacitance value is determined, C_{q1} can be used to indicate C_{q2}, as follows:

$${C}_{q 2} = \frac{{C}_{q} {C}_{q 1}}{{C}_{q 1} - {C}_{q}}$$

Since the capacitance size is positively related to the capacitance value, considering the simplest case, the size (side length) l of the qubit capacitor is:

$$l = k ( {C}_{q 1} + {C}_{q 2} ) = k ( {C}_{q 1} + \frac{{C}_{q} {C}_{q 1}}{{C}_{q 1} - {C}_{q}} ) = \frac{{kC}_{q 1}^{2}}{{C}_{q 1} - {C}_{q}} ;$$

wherein, k is a constant.

Deriving from C_{q1}, setting

$$\frac{dl}{{dC}_{q 1}} = \frac{{kC}_{q 1}^{2} - 2 {kC}_{q 1} {C}_{q}}{{( {C}_{q 1} - {C}_{q} )}^{2}} \geq 0 , {C}_{q 1} \geq 2 {C}_{q}$$

can be obtained, i.e., when C_{q1}=2C_{q}, the bit capacitance has the minimum size.

It can be seen that the minimum size is four times that of the “m-shaped” structure (regardless of the size of gap with the ground and in case of uniform width of qubit capacitor), which means that the double-island structure can increase space to the resonant cavities, the XY control line 106, the Z control line 105 and the read line 107, but the increased size is too large and cannot be reduced (due to the existence of the minimum size), which results in a larger overall chip size, and is different from that of other solutions. Also, the packaging box and the printed circuit board (PCB) should be customized. At the same time, the increase of chip size will also lead to a reduction in integration, which will inevitably affect all aspects of the design.

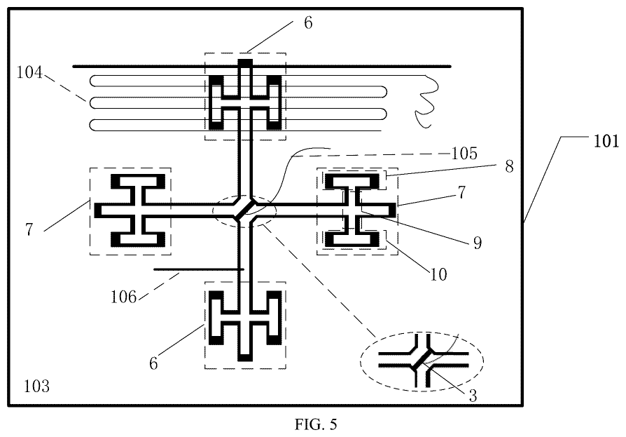

FIG. 5 is a structural diagram of a qubit capacitor provided by an embodiment of the present disclosure. As shown in FIG. 5, the qubit capacitor, includes: a first metal plate 1, a second metal plate 2, and a Josephson junction 3; wherein a first end of the Josephson junction 3 is connected with the first metal plate 1, and a second end of the Josephson junction 3 is connected with the second metal plate 2; a sub-metal sheet is arranged on the first metal plate 1 and/or the second metal plate 2; and the length of the sub-metal sheet is smaller than that of the first metal plate 1 and the second metal plate 2. In a specific embodiment, a first end of the Josephson junction 3 is connected to the first metal plate 1, and a second end of the Josephson junction 3 is connected to the second metal plate 2, so as to form a double-island qubit capacitor, enlarging the size of the qubit capacitor, reserving enough wiring space for the XY control line 106, the Z control line 105, and the like, and preventing mutual interference of the signals caused by the small distances among different control lines. However, as can be seen from the above contents, the size of a double-island qubit capacitor with the same capacitance is much larger than that of the cross-shaped qubit capacitor 102. Therefore, when a large number of double-island qubit capacitors are used to form a quantum chip, it may result in the size of the quantum chip being too large, which is not conducive to the normal application of the quantum chip. Accordingly, the qubit capacitor provided by the solution of the present disclosure further includes a sub-metal sheet arranged on the first metal plate 1 and/or the second metal plate 2. In the specific embodiment, a corresponding capacitor is generated between the sub-metal sheet and the chip ground 103, and the capacitor can be regarded as being connected in parallel with the capacitance value between the first metal plate 1 (or the second metal plate 2) and the chip ground 103. In this case, the capacitance value of the capacitor generated by the double-island qubit capacitor which is provided with the sub-metal sheet increases.

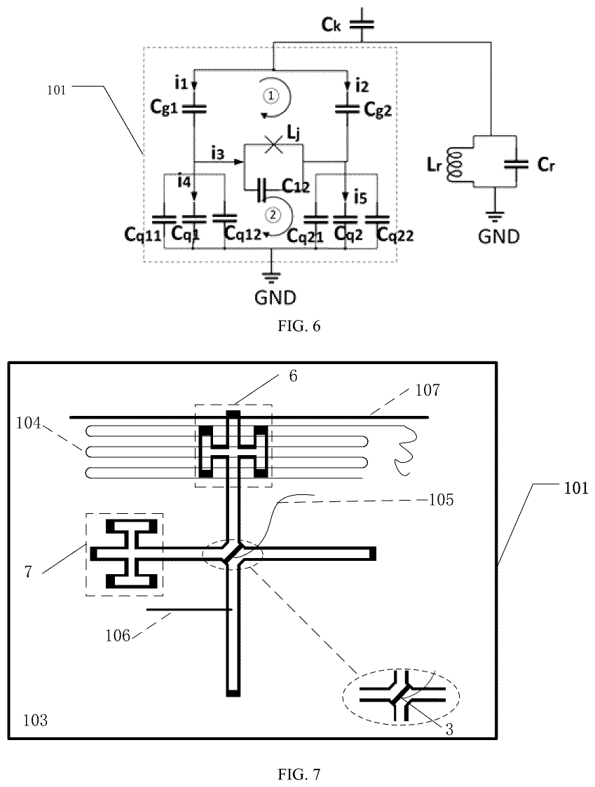

In a specific embodiment, the sub-metal sheet may be provided on both the first metal plate 1 and the second metal plate 2, or the sub-metal sheet may be provided only on the first metal plate 1 or only on the second metal plate 2. The shape of the sub-metal sheet can be I-shaped, snowflake-shaped and the like as mentioned in the solution of the present disclosure, and can also be of other structures, which is not limited herein. FIG. 5 is a structural diagram of a qubit capacitor with an I-shaped sub-metal sheet, FIG. 6 is an equivalent circuit diagram of a qubit capacitor provided by an embodiment of the present disclosure, and the circuit diagram shown in FIG. 6 corresponds to FIG. 5. As shown in FIG. 6, the qubit capacitor provided in this embodiment includes a Josephson junction 3, a first metal plate 1, a second metal plate 2, a chip ground 103, a resonator 104, a Z control line 105, an XY control line 106, a read line 107, and four I-shaped sub-metal sheets. The Josephson junction 3 is connected between the first metal plate 1 and the second metal plate 2, and the equivalent inductance is Lⱼ; self-capacitors C_{q1} and C_{q2} are formed between the first metal plate 1 and the chip ground 103, and between the second metal plate 2 and the chip ground 103, respectively; capacitors C_{q11}, C_{q12}, C_{q21}, and C_{q22} are formed between each of the sub-metal sheets and the chip ground 103, respectively; the first metal plate 1 and the second metal plate 2 are provided with a first I-shaped metal sheet 6 and a second I-shaped metal sheet 7; a coupling capacitor C₁₂ is formed between the first metal plate 1 and the second metal plate 2; the resonator 104, the Z control line 105, the XY control line 106, and the read line 107 are in non-coplanar coupling with a novel qubit capacitor (the first metal plate 1, the second metal plate 2 and the corresponding sub-metal sheets), wherein coupling capacitors C_{g1} and C_{q2} are formed between the resonator 104 and the first metal plate 1 (after the sub-metal sheet is connected in parallel) and between the resonator 104 and the second metal plate 2 (after the sub-metal sheet is connected in parallel), respectively. According to Kirchhoff laws, an equation set can be made as follows:

$$\{ \begin{matrix}I = {i}_{1} + {i}_{2} + {i}_{4} + {i}_{5} \\ {i}_{1} = {i}_{3} + {i}_{4} \\ {i}_{5} = {i}_{2} + {i}_{3}\end{matrix} ;$$

\textcircled{1} there is a circuit:

$${i}_{2} \frac{1}{j ω {C}_{g 2}} - {i}_{3} {Z}_{j} - {i}_{1} \frac{1}{j ω {C}_{g 1}} = 0 ;$$

\textcircled{2} there is a circuit:

$${i}_{3} {Z}_{j} + {i}_{5} \frac{1}{j ω {C}_{Q 2}} - {i}_{4} \frac{1}{j ω {C}_{Q 1}} = 0 ;$$

$${Z}_{j} = j ω {L}_{j} // \frac{1}{j ω {C}_{12}} = \frac{j ω {L}_{j} \cdot \frac{1}{j ω {C}_{12}}}{j ω {L}_{j} + \frac{1}{j ω {C}_{12}}} = \frac{j ω {L}_{j}}{1 - {ω}^{2} {L}_{j} {C}_{12}} ;$$

wherein, C_{Q1} is an equivalent capacitance formed by the first metal plate 1 and the sub-metal sheet, and C_{Q1}=C_{q1}+C_{q11}+C_{q12}; and C_{Q2} is an equivalent capacitance formed by the second metal plate 2 and the sub-metal sheet, and C_{Q2}=C_{q2}+C_{q21}+C_{q22};

After expressing i₂, i₃, i₄, and is in terms of i₁, the impedance in the dashed box is obtained as:

$$Z = \frac{U}{I} = \frac{\begin{matrix}{ω}^{2} {L}_{j} ( {C}_{Q 1} + {C}_{g 1} ) ( {C}_{Q 2} + {C}_{g 2} ) + \\ ( {ω}^{2} {L}_{j} {C}_{12} - 1 ) ( {C}_{Q 1} + {C}_{Q 2} + {C}_{g 1} + {C}_{g 2} )\end{matrix}}{j ω \{ \begin{matrix}[ {ω}^{2} {L}_{j} {C}_{Q 1} {C}_{Q 2} + ( {ω}^{2} {L}_{j} {C}_{12} - 1 ) ( {C}_{Q 1} + {C}_{Q 2} ) ] \\ ( {C}_{g 1} + {C}_{g 2} ) + {ω}^{2} {L}_{j} {C}_{g 2} {C}_{g 1} ( {C}_{Q 1} + {C}_{Q 2} )\end{matrix} \}} ;$$

From numerator=0, considering that C_{g1}, C_{q2} and C₁₂ are much smaller than C_{q1} and C_{q2}, the series resonance frequency can be obtained as:

$$ω = \sqrt{\frac{{C}_{Q 1} + {C}_{Q 2} + {C}_{g 1} + {C}_{g 2}}{\begin{matrix}{L}_{j} ( {C}_{Q 1} + {C}_{g 1} ) ( {C}_{Q 2} + {C}_{g 2} ) + {L}_{j} {C}_{12} \\ ( {C}_{Q 1} + {C}_{Q 2} + {C}_{g 1} + {C}_{g 2} )\end{matrix}}} \approx \sqrt{\frac{1}{{L}_{j} {C}_{Q}}} ;$$

wherein

$${C}_{q} = \frac{{C}_{q 1} {C}_{q 2}}{{C}_{q 1} + {C}_{q 2}}$$

is an approximate equivalent qubit capacitor.

Similarly, from denominator=0, considering that C_{g1}, C_{g2} and C₁₂ are much smaller than C_{q1} and C_{q2}, the parallel resonance frequency can be obtained as:

$$ω = \sqrt{\frac{( {C}_{1} + {C}_{2} ) ( {C}_{g 1} + {C}_{g 2} )}{{L}_{j} [ \begin{matrix}{C}_{1} {C}_{2} ( {C}_{g 1} + {C}_{g 2} ) + {C}_{g 2} + {C}_{g 1} ( {C}_{1} + {C}_{2} ) + \\ {C}_{12} ( {C}_{1} + {C}_{2} ) ( {C}_{g 1} + {C}_{g 2} )\end{matrix} ]}} \approx \sqrt{\frac{1}{{L}_{j} {C}_{Q}}} ;$$

wherein

$${C}_{Q} = \frac{{C}_{Q 1} {C}_{Q 2}}{{C}_{Q 1} + {C}_{Q 2}} .$$

Wherein, C_{Q} can be approximated as the capacitance value when C_{Q1} and C_{Q2} are connected in series, because the two metal sheets are basically the same size, i.e., C_{Q1}≈C_{Q2}≈2C_{Q}. Since the traditional double-island qubit capacitor is composed of two metal sheets with similar sizes, under the same size, it can be obtained:

$${C}_{q} \approx \frac{\frac{1}{2} {C}_{q 1} \cdot \frac{1}{2} {C}_{q 2}}{\frac{1}{2} {C}_{q 1} + \frac{1}{2} {C}_{q 2}} = \frac{1}{4} \frac{{C}_{q 1} {C}_{q 2}}{{C}_{q 1} + {C}_{q 2}} ;$$

Therefore, the qubit capacitor formed by the classical double-island structure is about ¼ of the qubit capacitor formed by the cross-shaped structure, i.e., at the same capacitance value, the size of the double-island structure is about four times that of the cross-shaped qubit capacitor. Due to the increased size of the qubit capacitor, the layout space reserved for the XY control line 106, the Z control line 105, and the read line 107 is larger, and the wiring requirement can be satisfied without sacrificing the isolation index among the signal lines.

In the specific embodiment, the capacitance value of the qubit capacitor provided by the present disclosure is the sum of the first metal plate 1, the second metal plate 2 and the respective sub-metal sheets. Therefore, the size of a single-arm capacitor structure decreases by increasing branches, which is equivalent to connecting capacitors in parallel, and the size of the double-island qubit capacitor decreases on the basis of ensuring the capacitance value of the capacitor. In the design process of a quantum chip, if the capacitance value of the required qubit capacitor changes, only the size of the sub-metal sheet needs to be adjusted, without the need of adjusting the size of the first metal plate 1 and the second metal plate 2, thereby reducing the design cost.

The present disclosure provides a qubit capacitor, including: a first metal plate, a second metal plate, and a Josephson junction; wherein a first end of the Josephson junction is connected with the first metal plate, and a second end of the Josephson junction is connected with the second metal plate; a sub-metal sheet is arranged on the first metal plate and/or the second metal plate; and the length of the sub-metal sheet is smaller than that of the first metal plate and the second metal plate. As can be seen, in the technical solution provided by the present disclosure, the first metal plate and the second metal plate are connected through the Josephson junction to form a double-island qubit capacitor, thereby providing a larger line layout space to prevent different signal lines from interfering with each other. Meanwhile, a sub-metal sheet is arranged on the first metal plate and the second metal plate, so as to achieve the purpose of increasing the shunt capacitance of the first metal plate and the second metal plate, and improving the equivalent capacitance value of the two parts of the double-island qubit capacitor. In addition, in the design stage of a qubit capacitor, the overall capacitance value of the qubit capacitor can be changed by adjusting the capacitance value of the sub-metal sheet without the need of adjusting the size of the qubit capacitor, thereby reducing the design cost.

It can be understood that the first metal plate 1 and the second metal plate 2 may be metal plates of any shape, and it is only necessary to ensure that the first metal plate 1 and the second metal plate 2 are connected by the Josephson junction 3. Also, the size of the first metal plate 1 and the second metal plate 2 can be the same or different. However, in a specific quantum chip array, multiple qubit capacitors are necessarily used for connection. When the difference in size or shape of the qubit capacitors is too large, it is unfavorable for the connection among different qubit capacitors.

In order to solve this technical problem, on the basis of the above embodiment, the first metal plate 1 and the second metal plate 2 include a first metal arm 4 and a second metal arm 5; and the angle between the first metal arm 4 and the second metal arm 5 is 90 degrees. Also, the first metal plate 1 and the second metal plate 2 have the same shape and the same area.

In this embodiment, the qubit capacitor formed by the first metal plate 1 and the second metal plate 2 is easy to use by limiting the size and shape of the first metal plate 1 and the second metal plate 2. At the same time, the angles of the metal arms of the first metal plate 1 and the second metal plate 2 are both 90 degrees, and the overlap areas between the first metal plate 1 and the chip ground 103 and between the second metal plate 2 and the chip ground 103 are increased, thereby improving the capacitance value of the qubit capacitor.

As shown in FIG. 5, a sub-metal sheet includes a first I-shaped metal sheet 6 and a second I-shaped metal sheet 7; wherein the first I-shaped metal sheet 6 and the second I-shaped metal sheet 7 includes a third metal arm 8, a fourth metal arm 9 and a fifth metal arm 10, respectively, and the third metal arm 8, the fourth metal arm 9 and the fifth metal arm 10 are linear metal arms; the third metal arm 8 is parallel to the fifth metal arm 10, and the third metal arm 8 and the fifth metal arm 10 are vertical to the fourth metal arm 9; a first end of the fourth metal arm 9 is connected with a midpoint of the third metal arm 8, and a second end of the fourth metal arm 9 is connected with a midpoint of the fifth metal arm 10; a center point of the fourth metal arm 9 of the first I-shaped metal sheet 6 is arranged on the first metal arm 4 of the first metal plate 1 and/or the second metal plate 2; and a center point of the fourth metal arm 9 of the second I-shaped metal sheet 7 is arranged on the second metal arm 5 of the first metal plate 1 and/or the second metal plate 2.

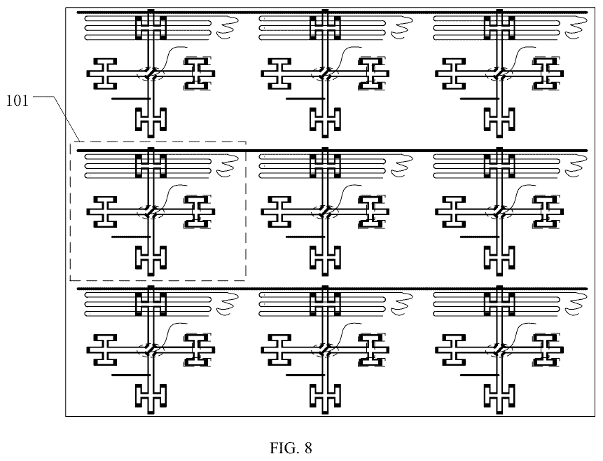

FIG. 7 is a structural diagram of another I-shaped qubit capacitor provided by an embodiment of the present disclosure. As shown in FIG. 7, when the sub-metal sheet is only arranged on the first metal plate 1, it can also achieve the purpose of changing the capacitance value of the qubit capacitor. The novel asymmetric double-island model of the “I-shaped” branch circuit used in FIG. 7 is adjusted on the basis of the original symmetrical structure, and the two parts of the double-island structure are no longer symmetric. It is only necessary to flexibly design the other half of the qubit capacitor of the double-island model, such as the newly added “I-shaped” branch circuit in this embodiment, and the other half continues to use a “boomerang-shaped” type consisting of the previous two sections of long arms. The design has the advantages of increasing the flexibility and the adjustability of the structure, and facilitating changes in parameter indicators during subsequent iterations and updates of the layout. As only one end of the branch circuit needs to be changed, high-efficient chip version iteration can be realized, and another section of the “boomerang-shaped” qubit capacitor arm can have a longer length to increase the distance between the bits. When the center distance between the bits increases, the overall space increases, and the space occupied by the resonator 104 remains unchanged. Then there will be more and larger space reserved for the signal lines (XY line and Z line) for routing layout, so that the distance between every two signal lines can also be made larger, and the isolation can be improved very well.

FIG. 8 is a schematic diagram of a qubit capacitor structure of a quantum chip provided by an embodiment of the present disclosure. As shown in FIG. 8, a plurality of qubit capacitors with I-shaped sub-metal sheets are connected to each other to form a qubit capacitor array.

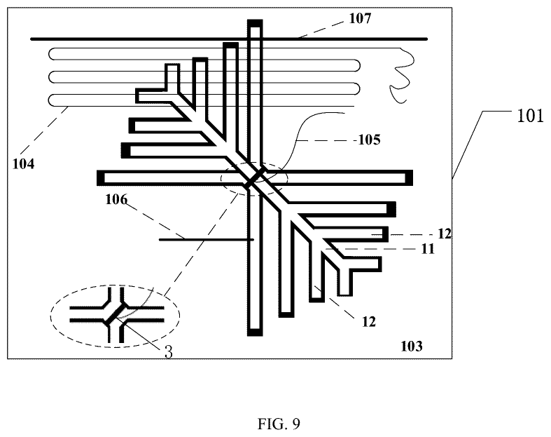

FIG. 9 is a structural diagram of a snowflake qubit capacitor provided by an embodiment of the present disclosure. As shown in FIG. 9, the sub-metal sheet is a snowflake metal sheet; the snowflake metal sheet includes a linear metal arm 11 and at least one angular metal arm 12; a right-angle vertex of each of the angular metal arms 12 is arranged on the linear metal arm 11, one end of the linear metal arm 11 is connected with an intersection point of the first metal arm 4 and the second metal arm 5 of the first metal plate 1 and/or the second metal plate 2; and an opening direction of each of the angular metal arms 12 is the same as that of the metal plate to which the linear metal arm 11 is connected.

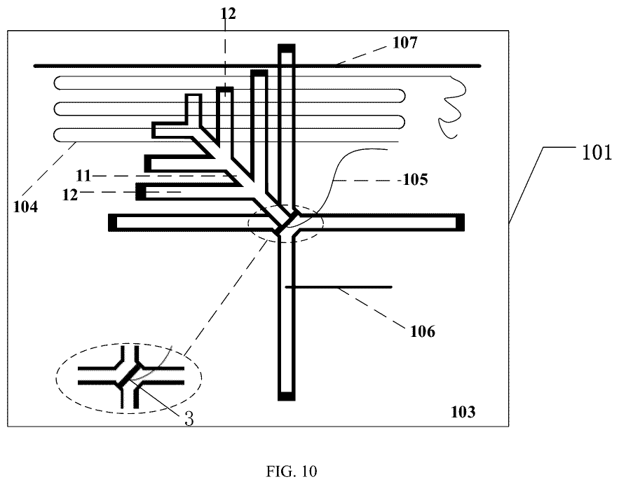

FIG. 9 shows a case where the first metal plate 1 and the second metal plate 2 are provided with sub-metal sheets. FIG. 10 is a structural diagram of another snowflake qubit capacitor provided by an embodiment of the present disclosure, where the sub-metal sheet is only arranged on the first metal plate 1, and it can also achieve the purpose of changing the capacitance value of the qubit capacitor. The novel asymmetric double-island model of the “snowflake” branch circuit used in FIG. 10 is adjusted on the basis of the original symmetrical structure, and combines the characteristics of the asymmetric bit double-island model and the “snowflake” branch circuit model. The design has the advantages that the spare space between the two arms can be effectively utilized, a plurality of newly-added branches can flexibly adjust the self-capacitance value, which facilitates changes in parameter indicators during subsequent iterations and updates of the layout. As only one end of the branch circuit needs to be changed, high-efficient chip version iteration can be realized. Besides, the “snowflake” branch circuit has more branches, resulting in more flexibility in regulation and more integration and space reuse in the structure. At the same time, the “boomerang” design of the other section of the double-island structure also ensures that the length of the single arm of the double-island structure is longer than that of the classical “m-shaped” and “cross-shaped” structures, which fully meets the requirement for wiring space. Whether it is a non-coplanar layout or a coplanar layout, the resonance cavity, XY signal lines and Z signal lines will have sufficient space, which facilitates the internal design of the chip.

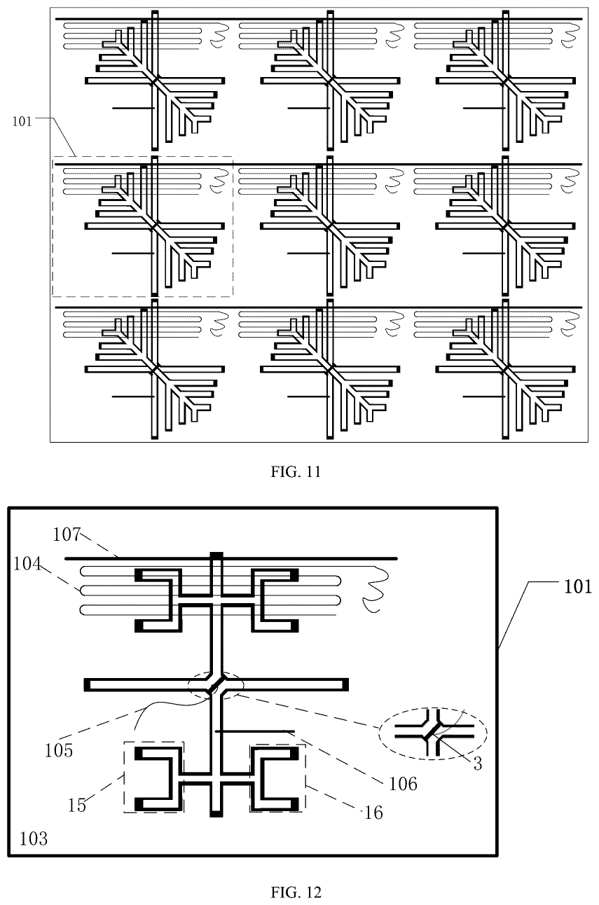

FIG. 11 is a schematic diagram of a qubit capacitor structure of another quantum chip provided by an embodiment of the present disclosure. As shown in FIG. 11, a plurality of qubit capacitors with snowflake sub-metal sheets are connected to each other to form a qubit capacitor array.

The novel double-island model of the snowflake branch circuit used in the embodiment can effectively utilize the spare space between the two arms, and a plurality of newly-added branches can flexibly adjust the self-capacitance value. On this basis, due to the increase of the multiple branches, the coupling capacitance value between the adjacent qubit capacitors is larger, which is more conducive to adjusting to a desired parameter index. Besides, the “snowflake” branch circuit has more branches, resulting in more flexibility in regulation and more integration and space reuse in the structure.

FIG. 12 is a structural diagram of a dumbbell-shaped qubit capacitor provided by an embodiment of the present disclosure. As shown in FIG. 12, the sub-metal sheet includes a first dumbbell-shaped metal sheet 13 and a second dumbbell-shaped metal sheet 14; wherein the first dumbbell-shaped metal sheet 13 and the second dumbbell-shaped metal sheet 14 include a first U-shaped metal arm 15, a second U-shaped metal arm 16 and a linear metal arm; a first end of the linear metal arm is connected with a midpoint of a bottom edge of the first U-shaped metal arm 15, and a second end of the linear metal arm is connected with a midpoint of a bottom edge of the second U-shaped metal arm 16; and a midpoint of the linear metal arm of the first dumbbell-shaped metal sheet 13 is fixed to the first metal arm 4 and/or the second metal arm 5 of the first metal plate 1, and a midpoint of the linear metal arm of the second dumbbell-shaped metal sheet 14 is fixed to the first metal arm 4 and/or the second metal arm 5 of the second metal plate 2.

In the specific embodiment, in order to control the working state of the qubit capacitor, the technical solution provided by the embodiment further includes a pulse regulation and control signal line and a frequency regulation and control signal line; wherein the pulse regulation and control signal line is connected with a control electrode of the qubit capacitor to control excited state of the qubit capacitor; and the frequency regulation and control signal line is connected with the Josephson junction 3 to control frequency of the qubit capacitor.

The pulse regulation and control signal line is a line for generating control pulses, which is generally positioned on the upper surface of the chip and connected with control electrodes on the surface of the chip. These control electrodes are usually metal films or metallized semiconductor films that interact directly with the quantum bit inside the chip. The pulse regulation and control signal line is mainly used for generating control pulses to realize the accurate control of the quantum bit. The amplitude, frequency and phase of these control pulses can be adjusted to achieve different control effects, for example, the speed of the quantum bit can be controlled by varying the frequency of the pulses; the rotation angle and direction of the quantum bit can be controlled by varying the amplitude and phase of the pulses. Through the control mode, operations such as acceleration, deceleration and stop of the quantum bit can be realized.

The frequency regulation and control signal line is mainly used for generating frequency regulation and control signals so as to control the frequency of the quantum bit. The frequency of these signals can be changed by adjusting the amplitude and phase of the signal lines, for example, the frequency of the quantum bit can be adjusted by varying the frequency of the signal lines; the amplitude and phase difference of the quantum bit can be controlled by varying the amplitude and phase of the signal lines. Through the control mode, operations such as frequency matching, filtering, signal separation and the like of the quantum bit can be realized.

In a quantum chip, the metal plate substrate in the qubit capacitor mainly serves to construct the quantum bit structure. The metal plate as a substrate can provide stable electrical properties, allowing for higher repeatability and consistency of the quantum bit. At the same time, the metal plate may also act as an intermediary between the quantum bit and the signal transmission line, directing signal energy from the transmission line to the quantum bit and vice versa.

The substrate material of the metal plate is usually a semiconductor material with high resistivity, such as silicon, gallium arsenide and the like. These materials are characterized by high conductivity and low noise, which can reduce resistance and thermal noise in the circuit, thereby reducing the specific heat errors in quantum bits. In addition, the surface of the metal plate usually needs to be polished to reduce the surface roughness, decrease the surface defect density, and improve the coupling efficiency between the metal plate and the quantum bit.

In the manufacture of a quantum chip, the metal plate is usually bonded to the substrate material to realize good thermal conduction and electrical connection. Common bonding techniques include direct bonding, metal thermocompression bonding, eutectic bonding, and the like. These techniques are capable of tightly bonding the metal plate to the substrate material, thus ensuring the stability and reliability of the quantum bit structure.

In this embodiment, the substrate of the first metal plate 1, the second metal plate 2 and the sub-metal sheet is silicon or sapphire connected with the metal plate by bonding technique, thereby providing stable electrical properties and efficient signal transmission for the quantum bit, and also ensuring the reliability and stability of the quantum bit structure.

Moreover, the present disclosure also provides a quantum chip including an array consisting of a plurality of qubit capacitors. In the specific embodiment, different qubit capacitors may be connected in a fixed coupling mode and an adjustable coupling mode. Fixed coupling means that the connection between a qubit capacitor and an adjacent circuit element or quantum bit has been determined during the manufacturing process and cannot be adjusted during operation. Generally, fixed coupling is achieved by metal connecting lines or shared electrodes. This coupling mode has the advantages of simple design and easy manufacture, and is suitable for a fixed connection between circuit elements or quantum bits. However, fixed coupling may not be suitable for scenarios that require flexible connections since it cannot be adjusted during operation. Adjustable coupling means that the connection between a qubit capacitor and an adjacent circuit element or quantum bit can be adjusted during operation, so as to achieve flexible connection and optimized performance. Adjustable coupling is generally implemented by programmable switches or regulators, which can open or close the connection between a qubit capacitor and an adjacent circuit element or quantum bit as needed. This coupling mode has the advantage of high flexibility and dynamically adjusting the connection relationship as required during operation, making it suitable for scenarios that require flexible connection and optimized performance. In this embodiment, different qubit capacitors are connected in a fixed coupling manner.

This embodiment provides a quantum chip including the above qubit capacitor, and the qubit capacitor includes: a first metal plate, a second metal plate, and a Josephson junction; wherein a first end of the Josephson junction is connected with the first metal plate, and a second end of the Josephson junction is connected with the second metal plate; a sub-metal sheet is arranged on the first metal plate and/or the second metal plate; and the length of the sub-metal sheet is smaller than that of the first metal plate and the second metal plate. As can be seen, in the technical solution provided by the present disclosure, the first metal plate and the second metal plate are connected through the Josephson junction to form a double-island qubit capacitor, thereby providing a larger line layout space to prevent different signal lines from interfering with each other. Meanwhile, a sub-metal sheet is arranged on the first metal plate and the second metal plate, so as to achieve the purpose of increasing the shunt capacitance of the first metal plate and the second metal plate, and improving the equivalent capacitance value of the two parts of the double-island qubit capacitor. In addition, in the design stage of a qubit capacitor, the overall capacitance value of the qubit capacitor can be changed by adjusting the capacitance value of the sub-metal sheet without the need of adjusting the size of the qubit capacitor, thereby reducing the design cost.

A qubit capacitor and a quantum chip are described in detail in the present disclosure. Each embodiment in the specification is described in a progressive manner, each embodiment focuses on the differences from other embodiments, and the same or similar parts among the embodiments can be referred to each other. For the device disclosed in the embodiments, the description thereof is relatively simple since it corresponds to the method disclosed in the embodiments. For the relevant information, please refer to the description of the method. It should be noted that those skilled in the art can make several improvements and modifications to the present disclosure without departing from the principles of the present disclosure, and these improvements and modifications also fall within the protection scope of the claims of the present disclosure.

Finally, it should also be noted that relationship terms such as first and second, etc. are used herein only to distinguish one entity or operation from another without necessarily requiring or implying any such actual relationship or order between those entities or operations. Moreover, the terms “comprise”, “include” or any other variation thereof, are intended to cover a non-exclusive inclusion, such that a process, a method, an article, or an apparatus comprising a list of elements includes not only those elements, but also other elements not explicitly listed or may include elements inherent to the process, method, article, or apparatus. Without further limitation, an element defined by the statement of “comprising a . . . ” does not exclude the further presence of additionally identical elements in a process, a method, an article or an apparatus comprising said element.

What is claimed is:

1. A qubit capacitor, comprising:
a first metal plate, a second metal plate, and a Josephson junction;
wherein a first end of the Josephson junction is connected with the first metal plate, and a second end of the Josephson junction is connected with the second metal plate;
a sub-metal sheet is arranged on the first metal plate and/or the second metal plate; and the length of the sub-metal sheet is smaller than that of the first metal plate and the second metal plate.

2. The qubit capacitor of claim 1, wherein the first metal plate and the second metal plate comprise a first metal arm and a second metal arm; and
an angle between the first metal arm and the second metal arm is 90 degrees.

3. The qubit capacitor of claim 1, wherein the first metal plate and the second metal plate have the same shape and the same area.

4. The qubit capacitor of claim 2, wherein the sub-metal sheet comprises a first I-shaped metal sheet and a second I-shaped metal sheet;
wherein the first I-shaped metal sheet and the second I-shaped metal sheet comprise a third metal arm, a fourth metal arm and a fifth metal arm, respectively, and the third metal arm, the fourth metal arm and the fifth metal arm are linear metal arms;
the third metal arm is parallel to the fifth metal arm, and the third metal arm and the fifth metal arm are vertical to the fourth metal arm;
a first end of the fourth metal arm is connected with a midpoint of the third metal arm, and a second end of the fourth metal arm is connected with a midpoint of the fifth metal arm;
a center point of the fourth metal arm of the first I-shaped metal sheet is arranged on the first metal arm of the first metal plate and/or the second metal plate; and
a center point of the fourth metal arm of the second I-shaped metal sheet is arranged on the second metal arm of the first metal plate and/or the second metal plate.

5. The qubit capacitor of claim 2, wherein the sub-metal sheet is a snowflake metal sheet;
the snowflake metal sheet comprises a linear metal arm and at least one angular metal arm;
a right-angle vertex of each of the angular metal arms is arranged on the linear metal arm, one end of the linear metal arm is connected with an intersection point of the first metal arm and the second metal arm of the first metal plate and/or the second metal plate; and
an opening direction of each of the angular metal arms is the same as that of the metal plate to which the linear metal arm is connected.

6. The qubit capacitor of claim 2, wherein the sub-metal sheet comprises a first dumbbell-shaped metal sheet and a second dumbbell-shaped metal sheet;
wherein the first dumbbell-shaped metal sheet and the second dumbbell-shaped metal sheet comprise a first U-shaped metal arm, a second U-shaped metal arm and a linear metal arm;
a first end of the linear metal arm is connected with a midpoint of a bottom edge of the first U-shaped metal arm, and a second end of the linear metal arm is connected with a midpoint of a bottom edge of the second U-shaped metal arm; and
a midpoint of the linear metal arm of the first dumbbell-shaped metal sheet is fixed to the first metal arm and/or the second metal arm of the first metal plate, and a midpoint of the linear metal arm of the second dumbbell-shaped metal sheet is fixed to the first metal arm and/or the second metal arm of the second metal plate.

7. The qubit capacitor of claim 1, wherein further comprising: a pulse regulation and control signal line and a frequency regulation and control signal line;
wherein the pulse regulation and control signal line is connected with a control electrode of the qubit capacitor to control excited state of the qubit capacitor; and
the frequency regulation and control signal line is connected with the Josephson junction to control frequency of the qubit capacitor.

8. The qubit capacitor of claim 1, wherein the substrate of the first metal plate, the second metal plate and the sub-metal sheet is silicon or sapphire connected with the metal plate by bonding technique.

9. A quantum chip comprising the qubit capacitor of claim 1.

10. The quantum chip of claim 9, wherein each of the qubit capacitors is connected in a fixed coupling manner.
